(19) United States
(12) Patent Application Publication
(10) Pub. No.: US 2010/0060153 A1
(43) Pub. Date: Mar. 11, 2010

(54) ORGANIC ELECTROLUMINESCENCE DEVICE, METHOD FOR MANUFACTURING THE SAME, AND ELECTRONIC APPARATUS

(75) Inventors: Masahiro Uchida, Chino-shi (JP); Tsuguya Kojima, Chino-shi (JP)

Correspondence Address: OLIFF & BERRIDGE, PLC, P.O. BOX 320850, ALEXANDRIA, VA, 22320-4850, US

(73) Assignee: SEIKO EPSON CORPORATION, Tokyo (JP)

(21) Appl. No.: 12/543,111

(22) Filed: Aug. 18, 2009

(30) Foreign Application Priority Data
Sep. 9, 2008 (JP) 2008-231294

(51) Int. Cl. H01J 1/62; B05D 5/06

(52) U.S. Cl. 313/504; 427/66

(57) ABSTRACT

An organic electroluminescence (EL) device having a light-emitting element including an organic luminescent layer provided between a positive electrode and a negative electrode, the organic EL device includes; a metal-containing layer disposed on the organic luminescent layer, provided between the organic luminescent layer and the negative electrode, and including an alkali metal or an alkali earth metal with a work function of 2.9 eV or lower; and an electron-transporting layer disposed on the metal-containing layer, provided between the metal-containing layer and the negative electrode, and including a low molecular weight compound for transportation of electrons, the low molecular weight compound having no repetitive molecular units formed by polymerization, wherein the organic luminescent layer includes of a luminescent macromolecular compound (polymer).

### BACKGROUND

1. Technical Field

The present invention relates to an organic electroluminescence device, a method for manufacturing the same, and an electronic apparatus.

2. Related Art

With the diversification of information devices, the demand for a flat display device having low power consumption and light weight has increased. As a flat display device, an organic electroluminescence device (hereinafter referred to as “organic EL devices”) including an organic luminescent layer is known.

For materials of the organic luminescent layer included in the organic EL device, either low molecular weight compounds (low molecular weight material) or macromolecular compounds (macromolecular material) can be used as long as injection of holes and electrons thereinto can be realized, the compounds can emit light generated by recombination of the injected holes and electrons which move therein, and the emitted light has properties arising from a difference in energy level between the highest occupied molecular orbit (HOMO) and the lowest unoccupied molecular orbit (LUMO). Here, “low molecular weight material” means a molecule that does not have any repetitive molecular units formed by polymerization, while “macromolecular material” means a polymer having repetitive molecular units.

Since the light-emitting phenomenon of low molecular weight materials was discovered before that of macromolecular materials, organic EL devices (low molecular weight type organic EL devices) using low molecular weight materials have been developed to the level of commercialization. A large number of such low molecular weight materials have rigid skeletons and a low solubility in organic solvents. Therefore, a method of forming such an organic luminescent layer needs a vapor phase reaction step such as vacuum deposition and a patterning step using a mask having a desired pattern.

Meanwhile, since a large number of luminescent nacromolecular materials have a relatively high solubility in organic solvents, the formation of the organic luminescent layer at a desired position and with a desired pattern can be easily achieved by performing a wet-coating process such as liquid ejection. Making full use of this advantage, the realization of an organic EL device having high resolution and high quality with low cost is expected.

On the other hand, it is known that the structure of a negative electrode injecting electrons into the organic luminescent layer significantly influences the operational stability of light emission of the organic EL device. The efficiency of the injection depends mainly on the difference in energy level, that is, the barrier height between the negative electrode and the organic luminescent layer. Accordingly, in order to improve electron-injection properties, various structures of the negative electrode have been proposed (for example, JP-A-2005-135624, JP-A-60-165771, JP-A-04-212287, JP-A-05-121172, JP-A-09-32763, JP-A-2005-203337, Japanese Patent No. 2760347).

An organic EL device (macromolecular organic EL device) that uses macromolecular materials to form an organic luminescent layer has many problems such as; low electron-injection performance; deterioration of metal having a low work function and high reactivity; and high sheet resistance. The above-mentioned documents disclose methods to solve those problems. Meanwhile, the organic EL device using a low molecular weight type material was developed before that using a high molecular type material, and structures of the negative electrode have almost been established. Therefore, if the structure of the negative electrode of the low molecular weight type organic EL device can be used in macromolecular type organic EL devices, rapid progress can be expected in this technology field.

The main difference in structure between the macromolecular organic EL device and the low molecular weight organic EL device is that the low molecular weight organic EL device has an electron-transporting layer where electron injection is facilitated by the negative electrode in the organic luminescent layer. In a large number of low molecular weight organic EL devices, an electron-transporting layer is formed with a low molecular weight material such as Alq₃ (tris(8-hydroxyquinolinato)aluminum) that has an electron-transporting property. According to such a structure, electrons are preferably injected into the organic luminescent layer and the light-emitting efficiency is improved. However, technology using such an electron-transporting layer in a macromolecular organic EL device is not disclosed in any of the above-mentioned documents 1 to 7.

The inventor of the invention conceived of the formation of an electron-transporting layer in a macromolecular organic EL device. However, a large number of the conductive macromolecular materials are p-type materials, in which holes easily move, while there are few conductive macromolecular materials of n-type, in which electrons easily move. Moreover, if a wet-coating method is used to form the layer of the macromolecular material having electron-transporting properties, an organic solvent that dissolves the macromolecular material having electron-transporting properties also dissolves the organic luminescent layer. Therefore, it is difficult to form a distinctive interface necessary for the layer structure.

The inventor fabricated an organic EL device in which an Alq₃ layer of low molecular weight material and a negative electrode are laminated on an organic luminescent layer of macromolecular material. Although light emission from the organic EL device having such a configuration was observed, the quality of the light was not satisfactory.

### SUMMARY

An advantage of some aspects of the invention is to provide an organic electroluminescence (EL) device in which electrons are preferably injected into a macromolecular luminescent layer and which has high operational stability achieved by adopting the configuration such that an organic EL element has a negative electrode made of a low molecular weight luminescent material. Another advantage is to provide a method for manufacturing the above-mentioned organic EL device. Further another advantage is to provide an electronic apparatus using such an organic EL device.

In line with results of various investigations, the inventor provided a layer for electron transporting (electron injection) at an interface between an electron-transporting layer made of low molecular weight material and an organic luminescent layer made of macromolecular material.

That is, in order to solve the above-mentioned problems, an organic EL device according to a first aspect of the invention has a light-emitting element including an organic luminescent layer provided between a positive electrode and a negative electrode, the organic luminescent layer including polymer of luminescent macromolecular compound; a metal-containing layer disposed on the organic luminescent layer, provided between the organic luminescent layer and the negative electrode, and including an alkali metal or an alkali earth metal with a work function of 2.9 eV or lower; and an electron-transporting layer disposed on the metal-containing layer, provided between the metal-containing layer and the negative electrode, and including a low molecular weight compound for transportation of electrons, the low molecular weight compound having no repetitive molecular units formed by polymerization.

According to the configuration mentioned above, a metal-containing layer including metal material with a low work function facilitates the electron injection at the interface between the electron-transporting layer and the organic luminescent layer, so that preferable electron injection using negative electrode can be performed. For this reason, an organic EL device with operational provability is provided.

Here, “includes an alkali metal or an alkali earth metal with a work function of 2.9 eV or lower” means that each of the metals exists as an elemental metal instead of a metal salt.

It is preferable to provide the electron-injection layer including at least one of alkali metal oxide, alkali metal fluoride, alkali earth metal oxide and alkali earth metal fluoride, at an electron-transporting layer side of the negative electrode. According to this configuration, the electron injection from the negative electrode into an electron-transporting layer is facilitated, so that highly efficient light-emitting and stable performance can be achieved.

It is preferable that the metal-containing layer contain at least Cs. According to this configuration, since a metal-containing layer is provided, which is capable of injecting holes at high efficiency to the organic luminescent layer, the light-emitting property of the organic EL device can be improved.

It is preferable that the organic EL device be of a top emission type, in which the light emitted from the organic luminescent layer passes through the negative electrode to the outside. A light-reflection layer is provided at the opposite side of the organic luminescent layer with the positive electrode that is transparent disposed therebetween. An optical resonator resonating light emitted from the organic luminescent layer is formed between the light-reflection layer and the negative electrode having semi-transparent reflectivity, so that the optical path length of the optical resonator can be adjusted on the basis of the thickness of the electron-transporting layer.

According to this configuration, since the optical resonator, which resonates the light emitted from the organic luminescent layer, is formed, light that has a resonant wavelength corresponding to the optical distance between the light-reflection layer and the negative electrode is amplified and emitted from each organic EL element. For example, by forming organic elements, each of them has a resonant wavelength corresponding to the wavelength of light of red (R), green (G), or blue (B), an organic EL device that can display images in full color can be provided. Furthermore, by adjusting the thickness of the electron-transporting layer, it becomes possible to provide an optical resonating structure with the desired optical path length. Thus, an organic EL device with high efficiency can be provided.

It is preferable that the organic EL device include at least two light-emitting elements, each emitting light of a different wavelength; a thickness of the electron-transporting layer be set according to the wavelength of the emitted light; and total layer thickness of each light-emitting element from a surface of the light reflection layer to a surface of the metal-containing layer positioned at an electron-transporting layer side be set substantially to be the same thickness.

According to this configuration, it is possible to provide a properly adjusted optical path on the basis of wavelength of emitted light, so that a preferable resonate structure can be provided. As a result, by improving the color purity of light emitted from light-emitting elements, an organic EL device of high quality in terms of light emission can be provided.

A method for manufacturing an organic EL device according to a second aspect of the invention is provided for an organic EL device. The organic EL device includes a light-emitting element having an organic luminescent layer provided between a positive electrode and a negative electrode, and a metal-containing layer disposed on the organic luminescent layer provided between the organic luminescent layer and the negative electrode. The metal-containing layer is formed by depositing a metal salt including a metal material selected from alkali metals and alkali earth metals which have a work function of 2.9 eV or lower.

Following this line of research, the deposition layer deposited by this method is not composed of a metal salt alone. The deposition layer (the metal-containing layer) includes an elemental metal other than a metal salt composed of the elemental metal. According to this method, the deposition layer including a desired metal material can be formed without handling of the metal material, which has a low work function and is hard to handle in atmosphere. Since a metal salt used for deposition material is stable in atmosphere, it is easy to handle, so that productivity is improved.

An electronic apparatus according to a third aspect of the invention includes the above-mentioned organic EL device.

According to this configuration, a highly reliable electronic apparatus including an organic EL device, which is capable of emitting light efficiently and has long lifetime, can be provided.

### BRIEF DESCRIPTION OF THE DRAWINGS

FIG. 1 is a schematic sectional view of organic EL device according to a first embodiment of the invention.

FIG. 2 is a schematic sectional view of organic EL device according to a second embodiment of the invention.

FIG. 3 is a sectional view of modified example of an organic EL device according to the second embodiment.

FIG. 4 is a perspective view of an electronic apparatus according to a third embodiment of the invention.

### DESCRIPTION OF EXEMPLARY EMBODIMENTS

### First Embodiment

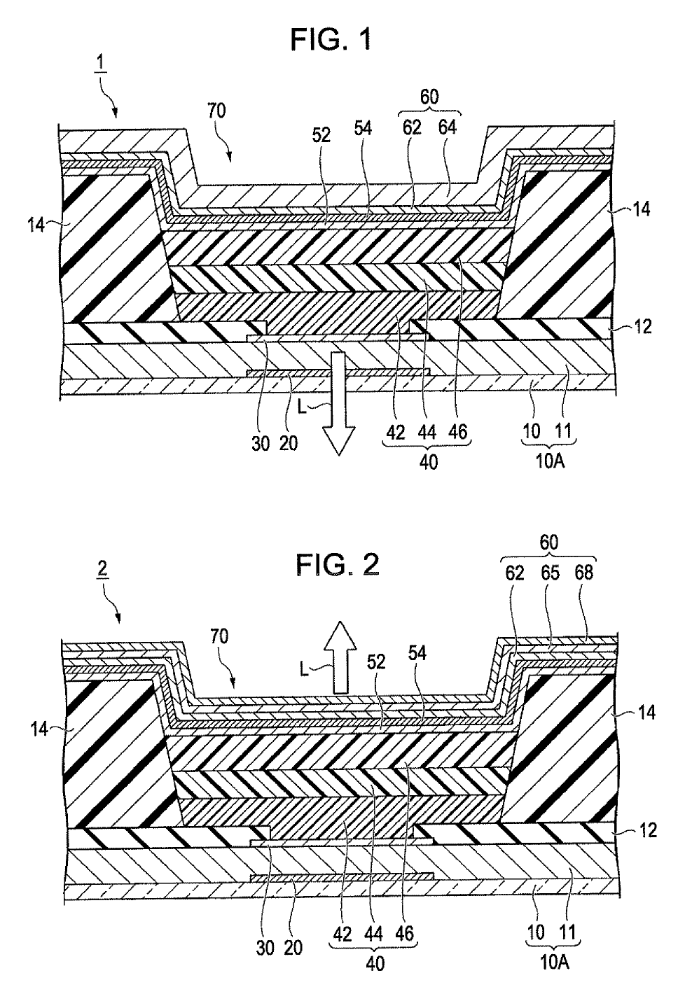

Hereinafter, an organic EL device according to a first embodiment of the invention is described with reference to FIG. 1. In order to help the understanding, the ratio of the thickness or size of each element is properly altered in all drawings.

FIG. 1 is a schematic sectional view of an organic EL device 1. As shown in FIG. 1, the organic EL device 1 includes a substrate 10A including an element substrate 10 and an element layer 11 having a drive element (not shown); a reflection layer (light reflection layer) 20 formed on the element substrate 10; a transparent pixel electrode (positive electrode) 30 formed on the substrate 10A; a pixel bank layer 12 having an opening overlapped with the pixel electrode 30 when viewed from a direction perpendicular to the substrates; and a common bank layer 14 formed on a pixel bank layer 12.

A light-emitting section 40 is formed in the area surrounded by the common bank layer 14, the pixel electrode, and the pixel bank layer. A common electrode (negative electrode) 60 is formed to cover an entire upper surface of the light-emitting section 40. An organic EL element (light-emitting element) 70 includes the pixel electrode 30, the light-emitting section 40, and the negative electrode 60.

The light-emitting section 40 includes; a hole-injection layer 42 that facilitates injection of holes from the pixel electrode 30; a hole-transporting layer 44 accelerating movement of the holes from the hole-injection layer 42; and an organic luminescent layer 46. They are laminated on the pixel electrode 30 in this order. Furthermore, a metal-containing layer 52 and an electron-transporting layer 54 are laminated on the organic luminescent layer 46.

The negative electrode 60 includes an electron-injection layer 62 and a negative electrode layer 64 covering entire surface of the electron-injection layer 62. Here, the electron-injection layer 62 covers the entire surface of the electron-transporting layer 54 which is disposed over the top surface and side wall of the common bank layer 14 and the organic luminescent layer 46.

The organic EL device 1 of the embodiment is a bottom emission type in which light L emitted from the organic luminescent layer 46 goes to outside through the pixel electrode 30. Hereinafter, each element is described in order.

A transparent substrate can be used for the element substrate 10. Examples of the transparent substrates include inorganic materials such as glass, quartz glass, and silicon nitride, and organic macromolecular materials (resin) such as acryl resin and polycarbonate resin. Furthermore, composites formed by laminating or mixing abovementioned materials may also be used as long as they are transparent In the present embodiment, glass is used for the element substrate 10.

The element layer 11 includes various wirings, drive elements, and inorganic or organic insulation layers to drive the organic EL device 1. Various wirings and drive elements are formed by etching after patterning by photolithography. Insulation layers are properly formed using known method such as deposition and sputtering.

The pixel electrode 30 is formed on the element layer 11. The transparent materials with a work function of 5 eV or higher are used to form the pixel electrode 30. Such materials are preferable to form the pixel electrode 30, because they can inject holes highly effectively. An example of those materials is metallic oxide such as ITO (Indium Tin Oxide). The present embodiment uses ITO.

furthermore, a pixel bank layer 12 covering an end portion of the pixel electrode 30 is formed on the element layer 11. The pixel bank layer 12 has an opening through which the corresponding pixel electrode 30 is exposed. The pixel bank layer 12 is formed of inorganic insulation material such as silicon oxide and silicon nitride, and formed by a known method such as etching using a mask in which patterns of the openings are provided at corresponding positions.

The common bank layer 14 is formed on the pixel bank layer 12 in such a manner that the common bank layer 14 surrounds the pixel electrode 30. Since the cross section of the common bank layer 14 has a tapered shape, the space surrounded by the common bank layer 14 has bigger opening at upper side than lower side. The common bank layer 14 is formed, for example, with photo curable acryl resin or a polyimide resin.

A hole injection layer 42 is formed on an exposed surface surrounded by the common bank layer 14. The exposed surface is composed of surfaces of the pixel electrode 30 and the pixel bank layer 12 in the present embodiment. The hole injection layer 42 keeps contact with the side surface of the common bank layer 14 and serves as a charge transfer layer which makes it easy to inject holes from the pixel electrode 30. Existing materials can be widely used for the hole injection layer 42; and PEDOT/PSS (Poly(3,4-ethylenedioxythiophene)) is used in the present embodiment.

A hole-transporting layer 44 and an organic luminescent layer 46 are formed on the hole injection layer 42 in this order, keeping contact with the side surface of the common bank layer 14. Existing materials can be widely used for those layers 44 and 46.

ADS259BE (brand name; American Dye Source Corp.) is an example of the materials for forming the hole-transporting layer 44, which is described as following chemical formula 1. For the materials for forming the organic luminescent layer 46, ADS109GE (brand name; American Dye Source Corp.) is an example of the macromolecular materials emitting light of green, which is described as following chemical formula 2; ADS111RE (brand name; American Dye Source Corp.) is an example of the macromolecular materials emitting light of red, which is described as following chemical formula 3; and ADS136BE (brand name; American Dye Source Corp.) is an example of the macromolecular materials emitting light of blue, which is described as following chemical formula 4.

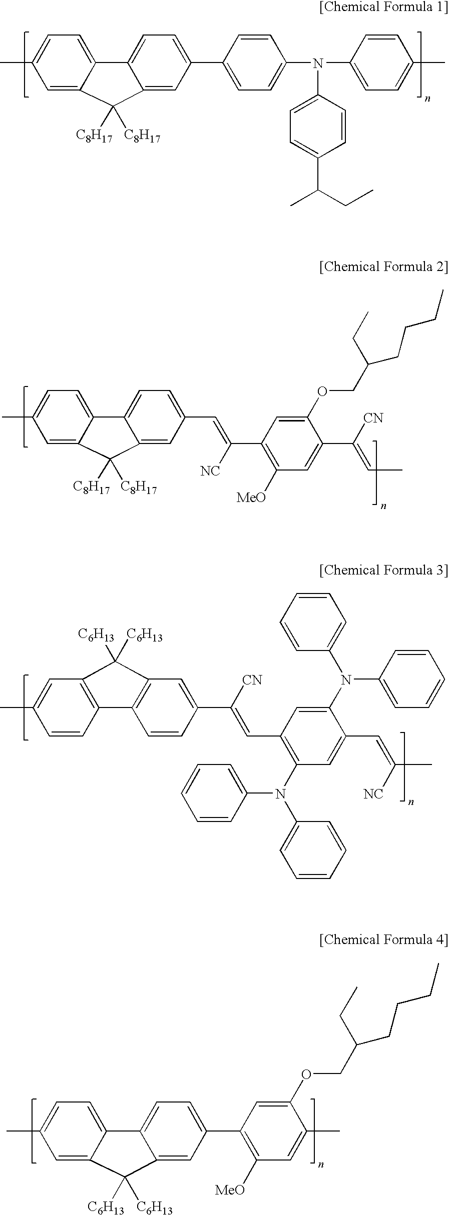

A metal-containing layer covering entire surface including an upper surface and a side surface of the common bank layer 14 is formed on the organic luminescent layer 46. The metal-containing layer 52 is formed by vacuum deposition with metal salt of alkali metal or alkali earth metal (a first metal material) with a work function of 2.9 eV or lower. Examples of the first metal material are Li, Cs, Ca, Sr, and Ba. In the present embodiment, a thin layer including Cs is formed by vacuum deposition of Cs₂CO₃, carbonate of Cs, to be the metal-containing layer 52. Vacuum deposition is conducted with a deposition apparatus of resistance heating type at a pressure of the order of 10⁻⁵ Pa and a deposition rate of 0.5 Å/sec.

Herein, “a layer including Cs” means that the layer includes at least an elemental metal of Cs, which can form Cs salt. The metal-containing layer 52 may include metal salt of deposition material. According to another experiment conducted in advance, the inventor of the invention indirectly confirmed that a vacuum deposition layer is composed of not only Cs salt, but also an elemental metal of Cs.

When laminated layers in which a layer of Al is deposited on a deposition layer that is formed using deposition source of Cs₂CO₃ is exposed in atmosphere, Al uncommonly reacts and foams, so that unevenness occurs in surface. If Cs₂CO₃ alone is formed in the deposition layer, considerable change will not occur in the laminated Al layer. This is probably because that the deposition layer includes elemental metal of Cs, and when the deposition layer was exposed to atmosphere, elemental metal of Cs in the layer was oxidized and absorbed moisture in atmosphere.

Accordingly, metal-containing layer 52 of the embodiment formed by deposition is the layer including Cs as an elemental substance.

In general, since the elemental metal of Cs has high reactivity and low melting point (28.5° C.), it easily deteriorates and melts. For this reason, the elemental metal of Cs is difficult to handle, and it is hard to form a layer including elemental metal of Cs. In the present embodiment, however, a metal salt that is stable and easy to handle in atmosphere is used as a starting material. Therefore, a layer including the elemental metal of Cs can be easily formed. Other examples of the deposition materials for the metal-containing layer 52 are sulfate, nitrate, metallic salt of inorganic acid series such as metal halide and the like, and metallic salt of organic acid series.

Furthermore, for the metal-containing layer 52 of this configuration, it is preferable that the thickness of the layer is sufficiently small not to reflect light. The metal-containing layer 52 of the present embodiment has a layer thickness of 0.5 nm. The electron injection performed between the organic luminescent layer 46 and the negative electrode 60 can be facilitated even if the thickness of the metal-containing layer 52 is as small as 0.5 nm.

An electron-transporting layer 54 is provided on the metal-containing layer 52. The layer 54 covers entire surface of the metal-containing layer 52 and has electron-transporting properties. Existing materials can be used for the electron-transporting layer 54 as long as the material can be used in organic EL devices with a low molecular weight luminescent material such as Alq₃, BCP (2,9-dimethyl-4,7-diphenyl-1,10-phenanthroline). In the present embodiment, Alq₃ is used for depositing a layer with a thickness of 20 nm.

A negative electrode 60 composed of a negative electrode layer 64 made of Al and an electron-injection layer 62 made of LiF covering the entire surface of the electron-transporting layer 54 is provided on the electron-transporting layer 54. Other than LiF, oxide or fluoride of alkali metals or alkali earth metals can be used for the electron-injection layer 62.

The electron-injection layer 62 of the present embodiment is formed at a thickness of 0.5 nm. The negative electrode layer 64 is formed at a thickness of 200 nm and it has sufficient light reflectivity and conductivity. The negative electrode layer 64 is connected to a negative electrode contact portion that is further connected to a negative electrode terminal (not shown).

An inorganic layer such as SiOxNy or the like (not shown) is formed on the negative electrode 60. A glass substrate is preferably attached on the inorganic layer with an epoxy resin therebetween to make, what is called, a solid sealing structure.

It may also be available to make, what is called, can sealing structure by using can sealing members. In the can sealing structure, a desiccant is provided in a recessed portion of the glass substrate. The recessed portion of the glass substrate is provided at the opposite side to the negative electrode 60. An epoxy resin is applied to a peripheral of the glass substrate and a substrate 10A, where the two substrates are overlapped when viewed from a direction perpendicular to the substrates. The organic EL device 1 of the present embodiment adopts that configuration.

According to the organic EL device 1 having such a configuration, since the metal-containing layer 52 including metal material of low work function facilitates the electron injection performed in an interface between the electron-transporting layer 54 and the organic luminescent layer 46, the electron injection from the negative electrode can be satisfactory performed. The metal-containing layer 52 is not required to be thick as long as it can lower the energy barrier height existing between the organic luminescent layer 46 and the negative electrode 60. Accordingly, by forming the metal-containing layer 52 to be a thin film, consumption quantity of the metal material with low work function can be considerably reduced, and it is possible to prevent occurrence of problems caused by deterioration of the metal material with high reactivity. Therefore, the organic EL device having high operational stability can be provided.

In the present embodiment, since the electron-injection layer 62 made of LiF is provided, the electron injection from the negative electrode layer 64 to the electron-transporting layer 54 is facilitated, thereby it is possible to realize highly efficient light emitting and continuously reliable driving.

In the present embodiment, the metal-containing layer 52 with low work function is formed by depositing a metal salt as a starting material in a vacuum condition. Accordingly, a deposition layer of the desired metal material can be formed without direct handling of the low work functional metal material having difficulty in handling in atmosphere, which results in a high productivity.

Although, the organic EL device 1 according to the present embodiment has one organic EL element 70, the organic EL device 1 may have a plurality of the organic EL elements 70. In such a case, the organic EL device can display an image with full colors by using the organic EL elements, each emitting light of red, green, or blue. In such an organic EL device, the negative electrode having the structure mentioned above is commonly provided for all organic EL elements.

Although the electron-injection layer 62 is provided in the organic EL element 70 in the present embodiment, the organic EL element without electron-injection layer 60 may also provided.

### Second Embodiment

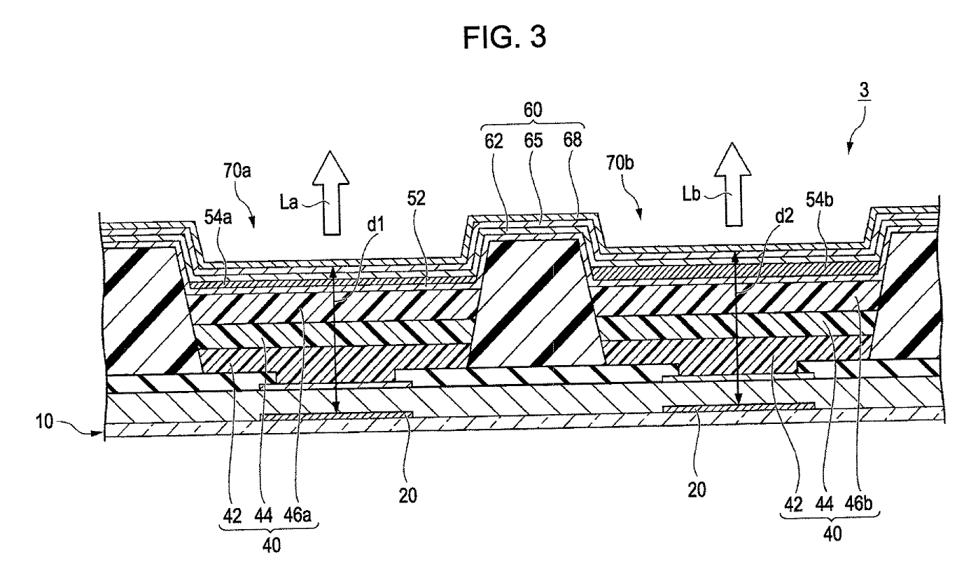

FIGS. 2 and 3 illustrate cross sectional views of an organic EL device 2 of a second embodiment. The organic EL device 2 of the second embodiment is partially the same as the first embodiment. The second embodiment differs from the first embodiment in that the organic EL device 2 of the second embodiment employs a top emission type structure in which light generated in the organic luminescent layer 46 emits towards the negative electrode 60. Accordingly, in description of the second embodiment, the same reference numerals designate the same components common to the first embodiment, so that the detailed description is omitted.

FIG. 2 is a schematic sectional view of the organic EL device 2. As seen in the drawing, a reflection layer 20 is disposed between an element substrate 10 and an element layer 11. The reflection layer 20 is placed at a position overlapping with a pixel electrode 30 when viewed from a direction perpendicular to the substrates. The reflection layer is made of Al—Nd alloy, and is formed by a known method such as mask patterning. In the present embodiment, the reflection layer 20 is described to be formed on the element substrate 10, however the reflection layer 20 may be formed in the element layer 11 or on the surface of the same.

A negative electrode layer 65 is formed on the entire surface of the electron-injection layer 62. The negative electrode layer 65 is an alloy layer formed by vacuum depositing a second metal material with a work function of 3.5 eV or higher and less than 4.2 eV and a third metal material with a work function of 4.2 eV or higher. Examples of the second metal material are Mg, Sc, Mn, In, Zr, and As, and examples of the third metal material are Al, Ag, Cu, Ni, and Au. The negative electrode layer 65 is connected to a negative electrode contact portion that is further connected to a negative electrode terminal (not shown). In the present embodiment, Mg is used as the second metal material and Ag is used as the third metal material.

The negative electrode layer 65 is an alloy layer formed with the second metal material and the third metal material. It has a lower work function than that of the elemental metal of the third metal material. It also has high stability against moisture or oxygen which is due to the advantageous properties of the third metal material.

According to another experiment conducted in advance by the inventor of the invention, it is ascertained that negative electrode layers formed by deposition of Mg and Ag together, each deposited at the Mg:Ag ratio of 1:10 (Ag: 91% by volume) or 40:1 (Ag: 2.4% by volume), have stability against moisture and oxygen. Accordingly, the volume ratio of the second metal material deposited to the third metal material deposited is preferably 1:10 to 40:1. Taking productivity and reproducibility into account, the deposition ratio of 5:1 to 20:1 is more preferable. In the present embodiment, co-deposition ratio of mg and Ag is 10:1 by volume ratio.

Thickness of the negative electrode 65 is preferably 20 nm or less for transparency. In order to keep the favorable electric conductivity in the direction along its surface, or low sheet resistance, the thickness of the electrode is preferably 5 nm or more. The thickness of the negative electrode layer 65 of the present embodiment is 15 nm.

A resonance layer 68 made of the third metal material is provided on the negative electrode layer 65. In the present embodiment, Ag is used to form the resonance layer. The resonance layer 68 is a semi-transparent layer that reflects a portion of light emitted from the organic luminescent layer 46. The negative electrode 60 having the resonance layer 68 works as a semi-transparent layer due to the semi-transparent resonance layer 68. Since the resonance layer 68 is made of the third metal material, the layer 68 reduces the sheet resistance of the negative electrode 60. The thickness of the resonance layer 68 of the present embodiment is 5 nm.

The resonance layer 68 and the reflection layer 20 constitute light resonance structure that resonates light therebetween. Only the light satisfying resonance wavelength corresponding to optical distance between the reflection layer 20 and resonance layer 68 is output from the organic EL element 70.

The light resonance structure sets an optical path of proper length corresponding to the desired wavelength of light. The light is resonated during reciprocating in the optical path. Therefore, for preferable resonance, it is necessary to adjust the distance (optical path length) between the reflection layer 20 and the resonance layer 68.

If the optical path length is adjusted by adjusting the thickness of the organic luminescent layer 46 and the negative electrode layer 65, it may reduce the amount of light emission and may lead to degradation of the operational stability. However, the organic EL device 2 of the present embodiment includes an electron-transporting layer 54 made of low molecular weight material. It is different from existing organic EL devices that include macromolecular material as the organic luminescent layer 46. Since the material of the electron-transporting layer 54 does not absorb or diffuse the light due to its sufficient transparency, the change in the thickness of the electron-transporting layer has little influence on emission of the light when the thickness of the optical length of the layer is adjusted. Accordingly, by adjusting thickness of the electron-transporting layer 54, the optical path length of the resonance structure is satisfactory controlled.

It is preferable to provide solid sealing structure on the negative electrode 60. The Organic EL device of the present embodiment has the above-mentioned configuration.

According to the organic EL device 2 of the above embodiment, since the organic EL device of top emission type with preferable light resonance structure is provided, the organic EL device of high quality with improved purity of light is realized.

Although one organic EL element 70 is described in the present embodiment, the organic EL device 1 may include a plurality of organic EL elements 70. FIG. 3 is a cross-sectional view of a modified organic EL device according to the present embodiment.

The organic EL device 3 includes two or more organic EL elements. In the FIG. 3, two organic EL elements 70a and 70b are shown. The organic EL elements 70a and 70b include organic luminescent layers 46a and 46b, respectively. The EL elements 70a and 70b emit lights La and Lb, respectively, which have different wavelength each other.

The thickness, or the light path length, of an electron-transporting layer 54a of the organic EL element 70a and an electron-transporting layer 54b of the organic EL element 70b are determined on the basis of corresponding wavelength of light emitted from respective organic luminescent layers. The thickness of the electron-transporting layer 54a and the electron-transporting layer 54b are d1 and d2, respectively. The electron-transporting layers, which are different in thickness, are formed by a known method such as mask deposition.

The other configurations of the organic EL elements 70a and 70b including a substrate 10A, a metal-containing layer 52, a negative electrode 60, and the like, have common structure. Therefore, these configurations can be manufactured by common process.

In the organic EL device 3 of this configuration, the optical path length corresponding to wavelength of light can be properly provided. Therefore, organic EL devices with high color quality can be realized by enhancing color purity of light emitted from individual luminescent element.

### Electronic Apparatus

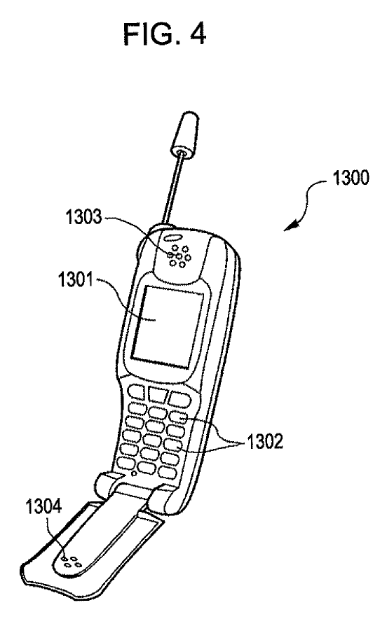

Hereinafter, an electronic apparatus according to the embodiment of the invention is described. FIG. 4 is a perspective view of an exemplary electronic apparatus including an organic EL device of the invention. Cellular phone 1300 shown in FIG. 4 has the organic EL device of the invention serving as a small-sized display 1301, a plurality of operation buttons 1302, a receiver 1303, and mouthpiece 1304. According to this configuration, a cellular phone with a display using the organic EL device of the invention has the high light-emitting efficiency and high reliability.

The organic EL device of the above embodiments is not limited to a cellular phone, but used very properly for a display for apparatuses such as an electronic book, a projector, a personal computer, a digital still camera, a television, a video tape recorder of viewfinder type or monitor direct-viewing type, a car navigation system, a pager, an electronic organizer, an electronic calculator, a word processor, a workstation, a picture phone, a POS terminal, an apparatus with a touch panel. According to the configuration, an electronic apparatus with a display having high quality and reliability can be provided.

Moreover, the organic EL device of the above embodiments can be used as a line head, so that an image forming apparatus (optical printer etc.) using the line head as a light source can be provided. By using this organic EL device, an optical printer of high reliability with uniform brightness can be provided.

Exemplary embodiments according to the invention have been described with reference to attached drawings, however, it should be understood that the invention is not limited to the disclosed exemplary embodiments and includes various changes in form and combination of the above-mentioned embodiments on the basis of design requirement without departing from the scope of the invention.

The entire disclosure of Japanese Patent Application No. 2008-231294, filed Sep. 9, 2008 is expressly incorporated by reference herein.

What is claimed is:

1. An organic electroluminescence (EL) device having a light-emitting element including an organic luminescent layer provided between a positive electrode and a negative electrode, the organic EL device comprising:
a metal-containing layer disposed on the organic luminescent layer, provided between the organic luminescent layer and the negative electrode, and including an alkali metal or an alkali earth metal with a work function of 2.9 eV or lower; and
an electron-transporting layer disposed on the metal-containing layer, provided between the metal-containing layer and the negative electrode, and including a low molecular weight compound for transportation of electrons, the low weight molecular compound having no repetitive molecular units formed by polymerization,
wherein the organic luminescent layer includes of a luminescent macromolecular compound (polymer).

2. The organic EL device according to claim 1, further comprising:
an electron-injection layer including at least one of alkali metal oxide, alkali metal fluoride, alkali earth metal oxide and alkali earth metal fluoride, at an electron-transporting layer side of the negative electrode.

3. The organic EL device according to claim 1, wherein the metal-containing layer contains at least Cs.

4. The organic EL device according to claim 1, wherein the organic EL device is a top emission type, in which light emitted from the organic luminescent layer is passed through the negative electrode to outside, the organic EL device comprising:
a light-reflection layer provided at opposite side of the organic luminescent layer with the positive electrode that is transparent disposed therebetween;
an optical resonator resonating light emitted from the organic luminescent layer and formed between the light-reflection layer and the negative electrode having semi-transparent reflectivity, wherein the optical path length of the optical resonator can be adjusted on the basis of the thickness of the electron-transporting layer.

5. The organic EL device according to claim 4, wherein the organic EL device includes at least two light-emitting elements, each emitting light of different wavelength from each other,
a thickness of the electron-transporting layer is set according to the wavelength of emitted light,
the total layer thickness of each light-emitting element from a surface of the light reflection layer to a surface of the metal-containing layer positioned at an electron-transporting layer side is set substantially to be the same thickness, and
each of the optical path lengths of the optical resonator structure is independently adjusted on the basis of corresponding layer thickness of the electron-transporting layer.

6. A method for manufacturing an organic EL device including a light-emitting element having an organic luminescent layer provided between a positive electrode and a negative electrode, and a metal-containing layer disposed on the organic luminescent layer provided between the organic luminescent layer and the negative electrode, the method comprising the steps of:
forming the metal-containing layer by depositing metal salt of metal material selected from alkali metals or alkali earth metals which have a work function of 2.9 eV or lower.

7. An electronic apparatus including an organic EL device according claim 1.
